(19) United States
(12) Patent Application Publication
(10) Pub. No.: US 2018/0123014 A1
(43) Pub. Date: May 3, 2018

(54) Thermoelectric Device and Method for Producing Same

(71) Applicant: Robert Bosch GmbH, Stuttgart (DE)

(72) Inventors: Tobias Zoller, Nuertingen (DE); Ricardo Ehrenpfordt, Korntal-Muenchingen (DE); Holger Rank, Ditzingen (DE); Frederik Ante, Stuttgart (DE)

(21) Appl. No.: 15/566,784

(22) PCT Filed: Apr. 22, 2016
(86) PCT No.: PCT/EP2016/058955

§ 371 Date: Oct. 16, 2017

(30) Foreign Application Priority Data
Apr. 29, 2015 (DE) 10 2015 207 857.4

(51) Int. Cl. H01L 35/32; H01L 35/06; H01L 35/10; H01L 35/34

(52) U.S. Cl. CPC H01L 35/32; H01L 35/34; H01L 35/10; H01L 35/06

(57) ABSTRACT

A thermoelectric device includes a printed circuit board, a component which is arranged on the printed circuit board, a cover which covers the printed circuit board, a thermoelectric generator, and a spring unit. The thermoelectric generator is thermally connected to the printed circuit board or metal paths on the printed circuit board and to the cover in order to generate an electric supply voltage for the component from the temperature difference between the printed circuit board and the cover. The spring unit elastically holds the thermoelectric generator between the printed circuit board and the cover.

### PRIOR ART

The present invention relates to a thermoelectric device, in particular a sensor device, which is fed by a thermoelectric generator. Another aspect of the invention relates to a method for producing such a thermoelectric device.

The “Internet of things” is considered to be one of the most important future developments in information technology. According to this concept, not only do humans have access to the Internet, but devices are also networked with each other via the Internet or a similar network. One area relates to the automation of production and the household by means of sensor devices which are installed at suitable points in order to detect variables such as, for example, temperature, pressure, illumination, etc., and to make the variables available via the network, for example wirelessly. In order to minimize the effort required for installation, operation, and maintenance, sensor devices are utilized that obtain the electrical energy required for operation from the surroundings, independently of batteries or an electric connection, using so-called “energy harvesters”. In addition to sensor devices comprising solar cells, sensor devices in particular comprising thermoelectric generators are known, which obtain energy from a temperature difference that is present in its surroundings, e.g., for the purpose of installing the sensor device on a heating system.

The thermoelectric generators utilized for this purpose typically consist of an upper substrate and a lower substrate which are connected to each other via pins which are made of a thermoelectric material and are thermally connected in parallel and are electrically connected in series. An electric voltage is generated within the thermoelectric generator by means of the Seebeck effect when there is a temperature difference between the upper substrate and the lower substrate. In order to allow for a close thermal contact, during operation, with two areas having different temperatures, when such a thermoelectric generator is packaged in an electronics housing, the thermoelectric generator is usually rigidly connected on its top side and bottom side comprising thermally conductive materials to housing walls which are in contact with different temperature zones during operation. As a result, however, any impacts, vibrations, or thermomechanical strains are directly transferred to the pins of the thermoelectric generator and can result in damage to the pins and, therefore, to the entire device.

DE 10 2011 075661 A1 discloses a thermoelectric arrangement which comprises a thermoelectric component which is disposed on a carrier and is located under a cover which is also disposed on the carrier. A plate-like, thermally conductive compensating material which has elastic properties, in particular, is disposed between a hot side and/or a cold side of the thermoelectric component and the carrier and the cover.

Thermomechanical strains, impacts or vibrations cause shear forces, in particular, however, which are absorbed only to a limited extent by a compensating material having a limited thickness. It is desirable to integrate a thermoelectric generator into a thermoelectric device such as a sensor device, for example, in a compact manner, and so the shear forces on the pins of the thermoelectric generator are reduced.

### DISCLOSURE OF THE INVENTION

A thermoelectric device comprising a printed circuit board, an electrically supplied component such as, e.g., a sensor, disposed on the printed circuit board, a cover which covers the printed circuit board, a thermoelectric generator, and a spring unit is therefore provided. The thermoelectric generator is thermally connected to the printed circuit board and to the cover in order to generate an electric supply voltage for the component from a temperature difference between the printed circuit board and the cover, wherein the spring unit resiliently holds the thermoelectric generator between the printed circuit board and the cover. The thermal connection of the thermoelectric generator to the printed circuit board can also consist of the thermoelectric generator being thermally connected to a metal structure which is formed as part of the printed circuit board. The thermal conductivity of metals is typically one hundred times greater than the thermal conductivity of an electrically insulating base material of a printed circuit board. For example, in a composite material which comprises base material and metal paths and forms the printed circuit board, heat is transported primarily via the metal paths, and so directional guidance is possible.

Another aspect of the invention relates to a method for producing such a thermoelectric device. The production method includes a step of disposing a component such as, for example, a sensor on a printed circuit board, a step of covering the printed circuit board with a cover, a step of thermally connecting a thermoelectric generator to the printed circuit board and to the cover, in order to generate an electric supply voltage for the component from a temperature difference between the printed circuit board and the cover, and a step of providing a spring unit which resiliently holds the thermoelectric generator between the printed circuit board and the cover.

It should be noted that terms related to spatial directions, such as “on”, “cover”, “upper” and “lower”, etc., in the present description merely relate to a relative orientation within the thermoelectric device, unless expressly indicated otherwise. In particular, there is no intention to refer to a preferred orientation of the device with respect to gravity.

### Advantages of the Invention

The fact that the cover covers the printed circuit board on which the component is mounted allows for a particularly compact design of the thermoelectric device, because the printed circuit board can simultaneously provide electric connections between the component, the thermoelectric generator, etc., and can function as a lower housing wall. Given that the thermoelectric generator is resiliently held by the spring unit between the printed circuit board and the cover, shear forces and other forces occurring in the production of the thermomechanical device due to, for example, reflow soldering or annealing steps; in the further processing when, for example, the thermoelectric device is to be connected to a further substrate; or during operation of the thermoelectric device due to thermomechanical strains, vibrations, impacts, etc., between the printed circuit board and the cover, are compensated for by the spring unit, which reduces the mechanical load on the thermoelectric generator. This makes it possible to continuously establish the thermal connection, according to the invention, of the thermoelectric generator to the printed circuit board and to the cover, by means of highly thermally conductive materials such as, for example, metal materials, in particular without the need to incorporate an e.g., plate-shaped compensating material into the heat path, whereby, overall, a reduction of the mechanical load on the thermoelectric pins of the thermoelectric generator can be achieved while ensuring a consistently good thermal connection.

It should be noted that the reduction of the mechanical load of the thermoelectric generator also advantageously extends to influences which occur due to mechanical and thermal loads during production, such as, for example, sawing the printed circuit board from a larger piece during transportation to the place of use, or during installation at the place of use.

According to one preferred refinement, the spring unit comprises at least one spring which is disposed between the printed circuit board and the thermoelectric generator. This protects the thermoelectric generator, already during the production of the thermoelectric device, against vibrations, for example, when sawing individual printed circuit boards—which comprise pre-installed thermoelectric generators—apart from a larger composite plate. Preferably, the spring is formed essentially from a base material of the printed circuit board. This makes it possible to design the spring in a simple way during the production of the printed circuit board, and so a separate production and assembly of the spring unit is superfluous.

According to one preferred refinement, the printed circuit board comprises a lower, middle, and upper printed circuit board layer, wherein the spring is essentially formed from the upper printed circuit board layer and the middle printed circuit board layer comprises a recess in the area of the spring. This makes it possible to design the spring in a particularly simple way in the case of a low height of the thermoelectric device by way of the recess providing freedom of movement for the spring and the lower printed circuit board providing protection.

According to one preferred refinement, a metal path is formed on the spring, which deflects the heat in a specific direction in order to provide for a thermal coupling to the underside, for example, by means of thermal vias through the printed circuit board. Furthermore, the metal paths can be efficiently formed in a joint process with electric conductive paths.

According to one preferred refinement, at least one metal passage is formed through the printed circuit board and thermally connects the thermoelectric generator to the underside of the printed circuit board. This allows for a particularly good thermal connection to a temperature range which lies under the printed circuit board, outside the thermoelectric device, during operation.

According to one preferred refinement, the spring unit comprises at least one spring which is disposed between the cover and the thermoelectric generator. This allows for particularly good protection of the thermoelectric generator against mechanical influences such as, for example, vibrations via the cover of the thermoelectric device.

According to one preferred refinement of the method according to the invention, the thermal connection includes a step of forming a sacrificial layer which at least partially hinders the resilience of the spring unit, a step of fixing the thermoelectric generator to the spring unit after the formation of the sacrificial unit, and a step of removing the sacrificial layer after the fixing of the thermoelectric generator. Given that the sacrificial layer stabilizes the spring unit during the fixation, so that the stability necessary for the fixation does not need to be provided by the spring unit itself, the spring unit can be designed to be particularly soft and protective for the thermoelectric generator.

### BRIEF DESCRIPTION OF THE DRAWINGS

FIG. 1 shows a schematic top view of a thermoelectric device according to one embodiment of the invention, wherein a cover is not shown.

FIG. 2 shows a schematic cross-section of the device from FIG. 1 along the arrow markings A-A.

FIG. 3 shows a schematic cross-sectional view of a thermoelectric device according to one further embodiment.

FIGS. 4A-B show a schematic top view and a side view of a spring of the device from FIG. 3.

FIGS. 5A-B show a schematic top view and side view of a spring of a thermoelectric device according to yet another embodiment.

FIGS. 6A-B show a schematic top view and side view of a spring of a thermoelectric device according to yet another embodiment.

FIG. 7 shows a flow chart of a production method, according to one embodiment, for the device from FIG. 1.

FIG. 8 shows a schematic cross-sectional view of a thermoelectric device according to one further embodiment.

Unless expressly mentioned otherwise, the same reference numbers in the figures refer to identical or equivalent elements.

### EMBODIMENTS OF THE INVENTION

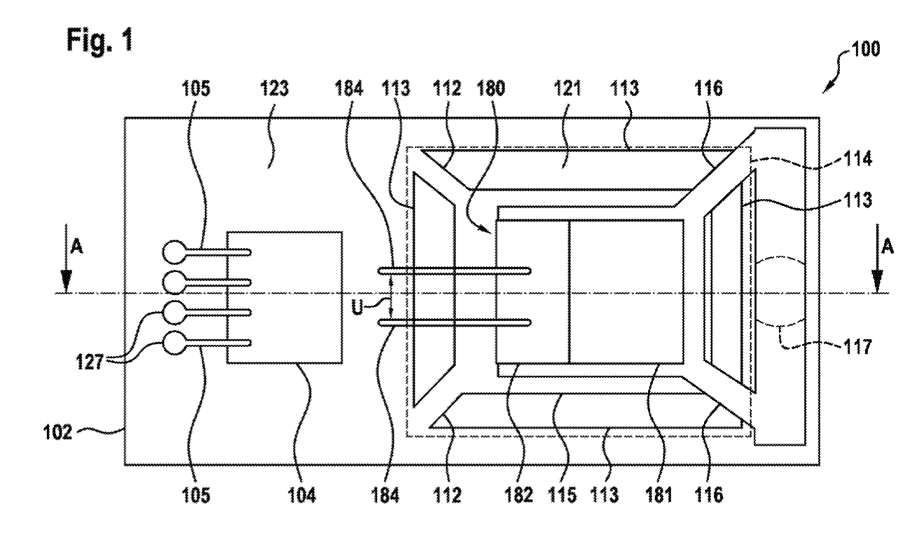

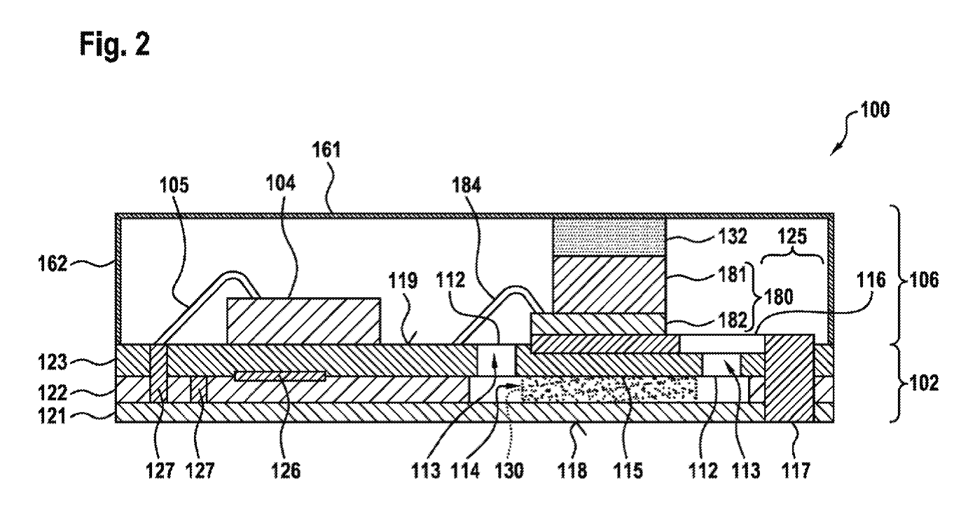

FIGS. 1 and 2 schematically show a sensor device 100, which is one example of a thermoelectric device, comprising a thermoelectric generator 180 according to a first embodiment. FIG. 1 is a top view of the thermoelectric device 100, wherein a cover 106, which is actually present, is not shown. FIG. 2 is a cross-sectional view of the same thermoelectric device 100, including the cover 106 which was omitted in FIG. 1, along a cutting plane indicated by the arrow markings A-A in FIG. 1.

The thermoelectric device 100 comprises a rectangular printed circuit board 102 which is formed in multiple layers, including a lower printed circuit board 121, a middle printed circuit board 122, and an upper printed circuit board 123 comprising an electrically insulating base material such as, e.g., fiber-reinforced plastic. The printed circuit board layers 121-123 are fixedly connected to each other, for example, by means of lamination. An electric conductive path 126 is shown between the upper printed circuit board layer 123 and the middle printed circuit board layer 122, by way of example, wherein further conductive paths—which are not shown, for the sake of clarity—can be formed in different levels on a top side 119 of the printed circuit board 102, which is formed by the upper printed circuit board layer 123, on an underside 118 of the printed circuit board 102, which is formed by the lower printed circuit board layer 121, and in intermediate layers between the printed circuit board layers 121-123. Furthermore, five electric plated through-holes 127 are shown, by way of example, which extend through the middle printed circuit board layer 122 or through the middle printed circuit board layer 122 and the upper printed circuit board layer 123, wherein further plated through-holes—which are not shown, for the sake of clarity—can be provided in order to electrically connect conductive paths in different levels to each other.

The thermoelectric device 100 also comprises a further component 104 disposed on the printed circuit board 102, for example an integrated circuit, a light-emitting diode, or a sensor, which is to be assumed to be a temperature sensor, by way of example, in the present embodiment, but which can also be any other type of sensor, such as, for example, a light sensor, a sound sensor, a field strength sensor, a vibration sensor, a position sensor, an acceleration sensor, a rotation sensor, a pressure sensor, or a moisture sensor, or any other type of electric component. The component 104 is mechanically fixed, for example, by means of adhesion, on the top side 119 of the printed circuit board 102 and is connected to electric plated through-holes 127 in the printed circuit board 102 by means of lead wires 105. In alternative embodiments, the lead wires can also be laid on any type of conductive structures on the substrate, which, in turn, can be electrically conductively connected to electric plated through-holes on another level. The thermoelectric generator 180 is also disposed on the printed circuit board 102. In addition to the component 104 and the thermoelectric generator 180, even further components can be disposed on the printed circuit board 102, such as sensors, microcontrollers, resistors, coils, radio modules, etc., which are not shown in the figures, however, for the sake of simplicity. Such components can be mechanically and electrically connected to the printed circuit board 102, for example via adhesion or bonding, wherein flip chip is also possible. In the present embodiment, components are disposed only on the top side 119 of the printed circuit board 102, although they can also be disposed on the underside 118 in alternative embodiments.

The thermoelectric generator 180 has two temperature sides 181, 182, which are positioned opposite each other, a cold side 181 of which faces away from the printed circuit board 102 and a hot side 182 of which faces the printed circuit board 102 in the present embodiment. It should be noted that, in alternative embodiments, the cold side 181 and the hot side 182 can also be reversed or each of the temperature sides 181, 182 can be operated both as a hot side and a cold side. The thermoelectric generator 180 is designed to supply the thermoelectric device 100, including the component 104, with an electric supply voltage U when there is a predetermined temperature difference between the temperature sides 181, 182. For this purpose, the thermoelectric generator 180 is electrically connected to the printed circuit board 102 by means of flexible wire bonds 184, and so the resultant supply voltage U can be utilized for operating the remaining components or for charging an energy accumulator (not shown).

The thermoelectric generator 180 is fixed via its cold side 181 to the cover 106 of the thermoelectric device 100 by means of heat-conductive paste 132. The cover 106 has a flat box shape, which is open toward the bottom, and has a roof surface 161 which has a matching outline in the projection perpendicularly to the printed circuit board 102, and has four lateral surfaces 162 which extend from the edge of the roof surface 161 perpendicularly downward to the printed circuit board 102, where they are fixedly connected to the printed circuit board 102, e.g., via adhesion. The heat-conducting paste 132 is used for thermally connecting the cold side 181 of the thermoelectric generator 180 to the cover 106 and, simultaneously, for tolerance compensation when the cover 106 is placed onto the printed circuit board 102 during the production of the thermoelectric device 100.

In the area of the thermoelectric generator 180, a recess 114 is formed in the middle printed circuit board layer 122, the outline of which completely encloses the thermoelectric generator in the projection perpendicular to the printed circuit board 102. Along the edge of the recess 114, multiple decoupling slots 113 are formed in the upper printed circuit board, between which thin webs 112 remain, which mechanically and thermally connect an island area 115 of the upper printed circuit board layer 123 enclosed by the decoupling slots 113 to the remaining area of the upper printed circuit board layer 123 located in the projection perpendicular to the printed circuit board 102 outside the recess 114.

In the present embodiment, the recess 114 and the island area 115 are rectangular, by way of example, although they can be designed in other embodiments to be, e.g., circular, or to have other suitable shapes, including different shapes. Furthermore, in the present embodiment, by way of example, four of the decoupling slots 113 are each formed having a trapezoidal shape with the long base side along one of the four lateral edges of the rectangular recess 114, and so, in each case, two leg sides of adjacent trapezoidal decoupling slots 113, extending in parallel to each other, delimit one of four webs 112, each of which extends from one corner of the rectangular recess 114 in the direction of the center of the recess 114.

On the top side 119 of the printed circuit board 102, a heat-conductive metal path 116 is formed essentially on the entire island area 115, on two of the webs 112, and in a levee area 125 extending between these webs, opposite the island area 115. The webs 112 are distinguished by the fact that they have very good heat-conducting properties. The metal path 116 can be formed, e.g., as a part of a structured metallization layer together with electric conductive paths (not shown in the figures) on the top side 119 of the printed circuit board 102, which simplifies the production of the thermoelectric device 100. The metal path 116 can also be formed independently of such conductor tracks, e.g., having a greater thickness, or can be formed of metal having high thermal conductivity. For example, the metal path 116 having a thickness of 18 to 100 μm is made of copper, the thermal conductivity of which, at 350 W/mK, is substantially higher than the thermal conductivity of typical printed circuit board materials. The metal path 116 can additionally be coated with an oxidation protection made of NiPdAu or similar alloys.

The thermoelectric generator 180 is fixed, via its hot side 182 and by means of heat-conductive adhesive or heat conductive paste, to the section of the metal path 116 covering the island area 115. Formed within the levee area 125 is a thermal plated through-hole 117 through the printed circuit board 102, which thermally connects the metal path 116 to the underside 118 of the printed circuit board 102. The thermal plated through-hole 117 can be designed, e.g., in the form of a fully copper-plated sleeve or a copper insert.

Since the recess 114 is formed underneath the island area 115, the aforementioned design allows the island area 115 to be elastically displaced and/or tilted in different spatial directions with respect to the rest of the printed circuit board 102 within limits which can be suitably predetermined by means of the number, arrangement, and dimensions of the webs 112, the elasticity of the base material of the printed circuit board 102, and the thicknesses of the printed circuit board layers 121 to 123. The webs 112 are therefore springs of a spring unit which resiliently holds the thermoelectric generator 180 between the printed circuit board 102 and the cover 106 and simultaneously provides a thermal connection of the thermoelectric generator 180 to the printed circuit board 102.

The number and dimensions of the webs 112 are to be preferably selected in such a way that the spring unit is flexible enough to absorb thermomechanical strains or to reduce vibrations, but is simultaneously stiff enough to fix the thermoelectric generator 180 on the island area 115 during the production of the thermoelectric device 100 by means of adhesion or bonding, for example. Therefore, a parallel connection of multiple thin resilient webs 112 is particularly suitable, and so the individual webs 112 can absorb strains, but the spring unit, overall, is so stiff that the island area 115 is sufficiently stable in its position during installation of the thermoelectric generator 180.

For example, the spring unit has a total spring rate between 5 kN/m and 500 kN/m with respect to horizontal and vertical deflection. An advantageously particularly softly resilient hold of the thermoelectric generator 180 having a spring rate below 5 kN/m can be made possible by way of the island area 115 being supported by a temporary sacrificial layer 130 during the installation of the thermoelectric generator 180. This sacrificial layer 130 can be formed, for example, from a thermally decomposable polymer, a water soluble adhesive, or the like. By means of this temporary stiffening of the spring unit, reliable assembly and wire bonding of the thermoelectric generator 180 is ensured.

For example, in the present embodiment, the thickness of the upper printed circuit board layer 123, from which the resilient webs 112 are formed, is between approximately 0.2 mm and 0.4 mm, the width of the webs 112 is between 0.2 mm and 1 mm, and the length is less than 2 mm, whereby the total spring rate of the spring unit can be reduced to 1 kN/m. In this case, a modulus of elasticity of 30 GPa is assumed for printed circuit boards or glass fiber epoxy system.

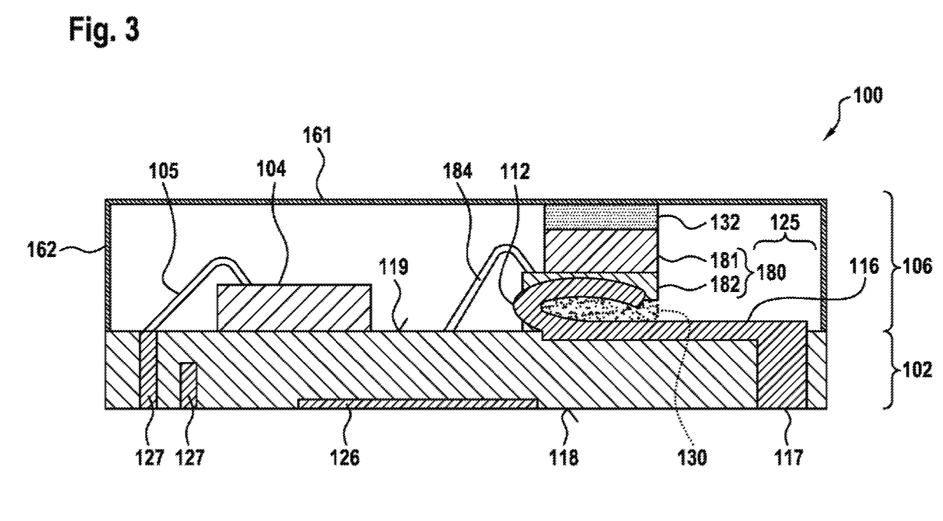

FIG. 3 shows a schematic cross-sectional view of a thermoelectric device 100 according to a further embodiment, in which the spring unit is not integrated into the printed circuit board 102, as is the case in the above-described first embodiment. Instead, a single-layer standard printed circuit board 102 is utilized in this case, while the spring unit comprises a suitably shaped metal spring 112 which is made, e.g., of copper and is mechanically and thermally connected via adhesion, conductive adhesion, or soldering to the metal path 116 formed on the top side 119 of the printed circuit board 102 and to the cold side 181 of the thermoelectric generator 180. A sacrificial layer 130 can be utilized during the production, as in the first embodiment.

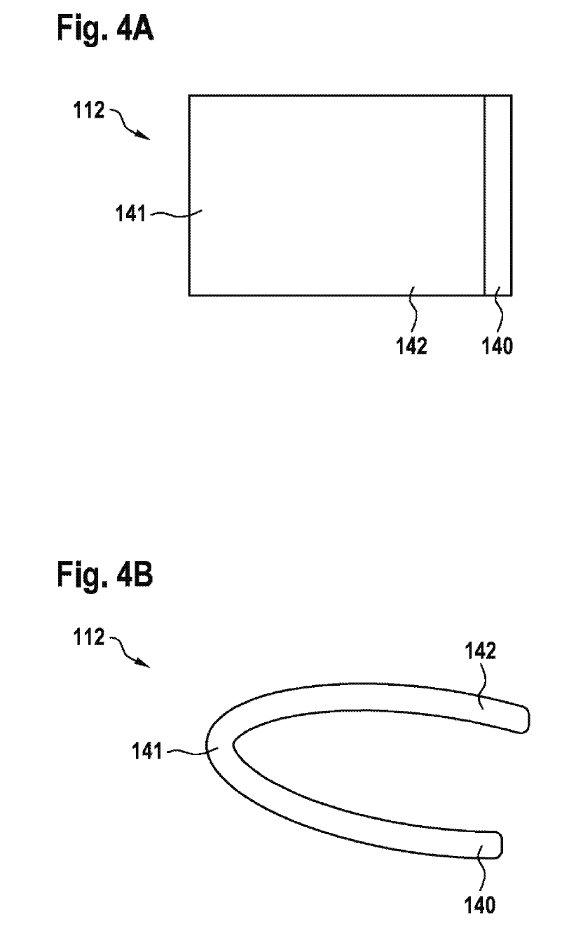

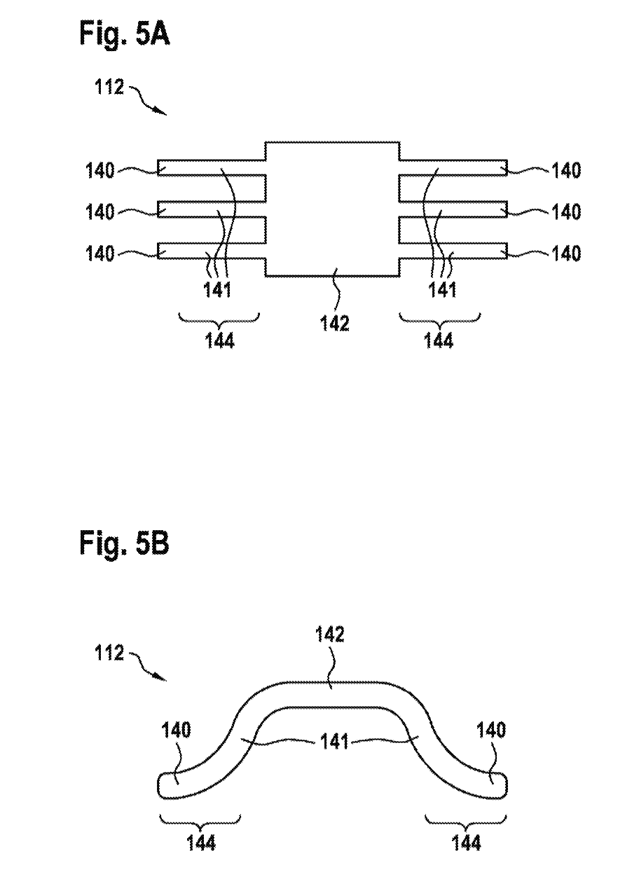

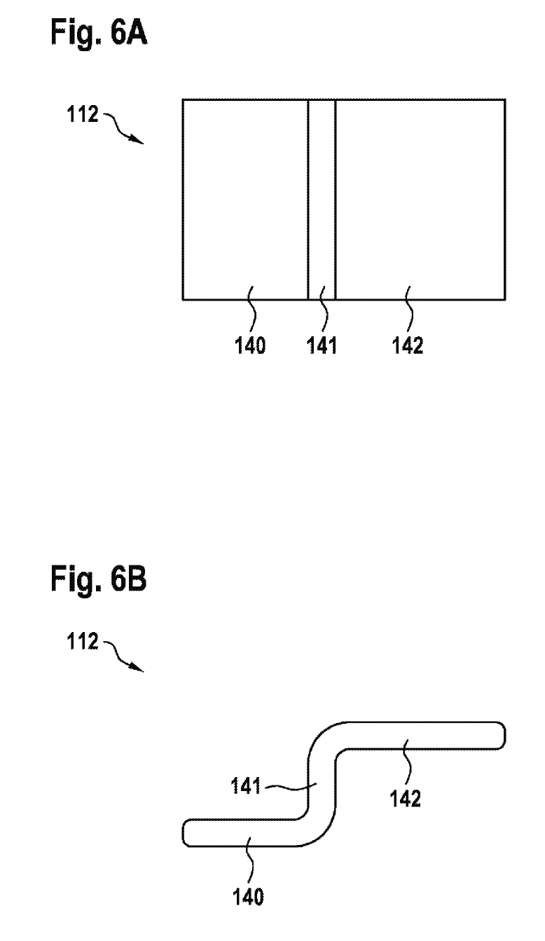

FIG. 4A shows a schematic top view of the spring 112 of the thermoelectric device 100 from FIG. 3, while FIG. 4B shows a schematic side view of the same spring 112. The spring 112 is formed by bending a piece of sheet metal having a basic rectangular shape back onto itself and comprises a printed circuit board connection section 140 for connection to the printed circuit board 102, a generator connection section 142 for connection to the thermoelectric generator 130 and an elastically bendable spring section 141 located between the printed circuit board connection section 140 and a generator connection section 142. Such springs can be produced having diverse shapes by means of punching or etching sheet metal, followed by deep drawing. For example, in alternative embodiments, the spring 112 can be designed having an [symbol] -shaped profile as in FIGS. 5A-B or an S-shaped profile as in FIGS. 6A-B, while the design of the thermoelectric device 100 remains otherwise unchanged. Other spring geometries are also conceivable, however.

In the case of the spring 112 shown in FIGS. 5A-B, in particular, the thermomechanical strain of the system can be compensated for by means of a large number of thin spring legs 144 which extend in parallel to each other from opposite corners of the rectangular generator connection section 142, and a relatively high total spring rate is simultaneously ensured. For reasons of symmetry and stability, such a spring 112 preferably comprises at least four spring legs 144, wherein two spring legs are sufficient, however.

Depending on the exact geometry and the metal that was selected, the thickness of the metal spring 112 is preferably not less than 0.1 mm, and the width is also not less than 0.1 mm. Despite the modulus of elasticity, which is 130 GPa for copper, for example, and is higher as compared to the printed circuit board material utilized for the spring in the first embodiment, a spring rate of a few kN/m can be achieved by means of a suitable selection of the geometry also in the case of the metal springs 112. For example, a spring rate of ˜10 kN/m can be achieved for one of the spring legs 144 by way of the spring 112 shown in FIGS. 5A--B being designed with a length of more than 2 mm. Alternatively, the metal springs can also be made of aluminum (modulus of elasticity of approximately 70 GPa), whereby lower spring stiffnesses can be achieved. Both copper and aluminum can be coated with an oxidation protection.

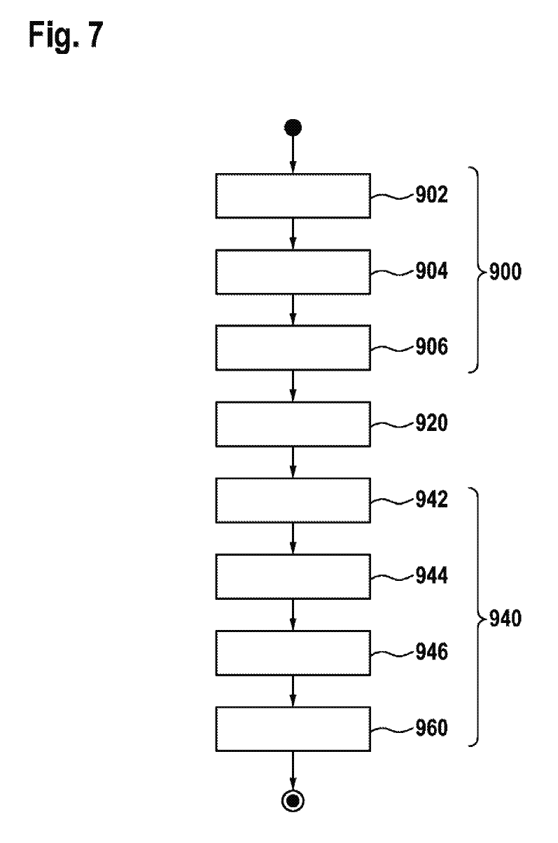

A production method for a thermoelectric device 100, as shown in FIG. 1, is to be described with reference to a flow chart shown in FIG. 7, wherein reference is also made to FIGS. 1 and 2.

First, in step 902, a spring consisting of webs 112 is formed from a printed circuit board layer which forms the upper printed circuit board layer 123 in the thermoelectric device 100 by punching out decoupling slots 113 which surround an island area 115, as shown in FIG. 2. Secondly, a recess 114 is punched out of a further printed circuit board layer which is of the same size and will form the middle printed circuit board layer 122 in the thermoelectric device 100. Next, the upper printed circuit board layer 123, the middle printed circuit board layer 122, and a lower printed circuit board layer 121, which is also of the same size, are laminated to form a printed circuit board 102 in such a way that the recess 114 is disposed under the spring 112. Carried out in this way, the steps 902, 904 and 906, together with further steps, if necessary, for forming conductive paths, plated through-holes, etc., form a higher-order step 900 of providing a printed circuit board 102 comprising an integrated spring unit for resiliently holding a thermoelectric generator in the thermoelectric device 100 to be produced.

Subsequently, in step 920, a component 104 to be electrically supplied, such as, e.g., a sensor, and further electronic components are installed on the printed circuit board 102 and are electrically connected to the printed circuit board 102 by means of wire bonding or the like. In the subsequent step 942, which can also take place already within the scope of step 900, however, a sacrificial layer 130 comprising a polymer material is provided in the recess 114 in the printed circuit board 102, which reinforces the spring unit. In step 944, the thermoelectric generator 180 is fixed on the island area 115 held by means of the webs 112 of the spring unit and by the sacrificial layer 130. In step 946, the sacrificial layer 130 is removed, e.g., by the effect of heat or by means of a suitable solvent. In the following step 960, a heat-conductive adhesive paste 132 is applied onto the thermoelectric generator 180 and a cover 106 is installed over the printed circuit board. 102, and so the thermoelectric generator 180 comes into contact with the heat-conductive adhesive paste 132 and adheres on the cover 106. In the end, the thermoelectric generator 180 is resiliently held between the printed circuit board 102 and the cover 106.

The steps 942, 944, 946 and 960, together with further steps, if necessary, form a higher-order step 940 of the thermal connection of the thermoelectric generator 180 to the printed circuit board 102 and to the cover 106, and so, during operation of the thermoelectric device 100 produced therewith, the thermoelectric generator 180 can generate an electric supply voltage U for the component 104 and the thermoelectric device 100 as a whole from a temperature difference between the printed circuit board 102 and the cover 106.

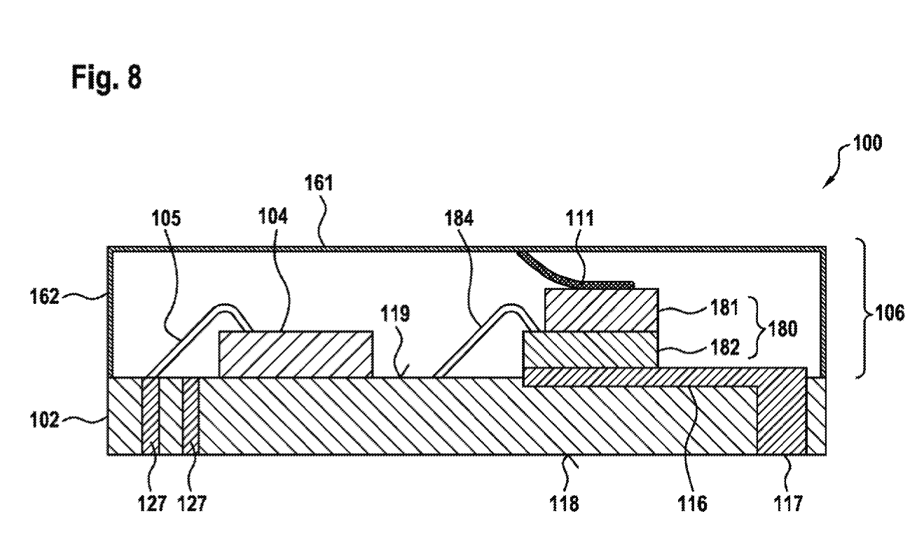

FIG. 8 is a schematic cross-sectional view of a thermoelectric device 100 according to a further embodiment, in which the printed circuit board 102 is designed similarly to the embodiment shown in FIG. 3, with the deviation, however, that the hot side 182 of the thermoelectric generator 180 is fixed on the metal path 116 directly by means of adhesion, soldering, or the like, without a spring therebetween, and is therefore rigidly connected to the printed circuit board 102. Instead, the thermoelectric device 100 comprises an upper spring 111 which is fixed on the cover 106 and resiliently mechanically and thermally contacts the thermoelectric generator 180 on its cold side 181. This embodiment offers the same advantages with respect to the reduction of shear forces resulting from thermomechanical strains or vibrations as the preceding embodiments. Additionally, the production of the thermoelectric device 100 is simplied, however, because the thermoelectric generator 180 is rigidly connected to the substrate and, in this state, can be electrically contacted by means of bonding before the cover is installed in one of the final production steps. In addition, the spring rate of the upper spring 111 can be selected to be arbitrarily soft, which allows for a very soft and flexible holding of the thermoelectric generator 180.

The upper spring 111 can be designed having different shapes and can be made of a metal such as copper or aluminum, as is the case with the springs shown in FIGS. 3 to 6. It is also possible to combine the above-described embodiments by way of the spring unit comprising both a lower spring 112 and an upper spring 111 which resiliently hold the thermoelectric generator from both sides.

1. A thermoelectric device, comprising:
a printed circuit board;
a component disposed on the printed circuit board;
a cover configured to cover the printed circuit board;
a thermoelectric generator thermally connected to the printed circuit board and to the cover to generate an electric voltage supply for the component from a temperature difference between the printed circuit board and the cover; and
a spring unit configured to resiliently hold the thermoelectric generator between the printed circuit board and the cover.

2. The thermoelectric device as claimed in claim 1, wherein the spring unit comprises at least one spring disposed between the printed circuit board and the thermoelectric generator.

3. The thermoelectric device as claimed in claim 2, wherein the at least one spring is essentially formed from a base material of the printed circuit board.

4. The thermoelectric device as claimed in claim 3, wherein:
the printed circuit board comprises a lower printed circuit board layer, a middle printed circuit board layer, and an upper printed circuit board layer;
the at least one spring is essentially formed from the upper printed circuit board layer; and
the middle printed circuit board layer has a recess in an area of the at least one spring.

5. The thermoelectric device as claimed in claim 2, wherein:
a metal path is formed on the at least one spring; and
the metal path is configured to thermally connect the thermoelectric generator to the printed circuit board.

6. The thermoelectric device as claimed in claim 1, wherein:
a metal plated through-hole is formed through the printed circuit board; and
the metal plated through-hole is configured to thermally connect the thermoelectric generator to an underside of the printed circuit board.

7. The thermoelectric device as claimed in claim 2, wherein the spring unit comprises at least one further spring disposed between the printed circuit board and the thermoelectric generator.

8. A method for producing a thermoelectric device, including:
arranging a component on a printed circuit board;
covering the printed circuit board with a cover;
thermally connecting a thermoelectric generator to the printed circuit board and to the cover to generate an electric supply voltage for the component from a temperature difference between the printed circuit board and the cover; and
providing a spring unit which resiliently holds the thermoelectric generator between the printed circuit board and the cover.

9. The method as claimed in claim 8, wherein:
thermally connecting the thermoelectric generator to the printed circuit board and to the cover includes:
forming a sacrificial layer which at least partially hinders the resilience of the spring unit;
fixing the thermoelectric generator on the spring unit after forming the sacrificial layer; and
removing the sacrificial layer after fixing the thermoelectric generator.

10. The method as claimed in claim 8, wherein:
providing the spring unit includes:
forming a spring from an upper printed circuit board layer;
forming a recess in a middle printed circuit board layer; and
laminating the upper printed circuit board layer, the middle printed circuit board layer, and a lower printed circuit board layer to the printed circuit board such that the recess is disposed under the spring.
